(19) United States
(12) Patent Application Publication
(10) Pub. No.: US 2012/0220130 A1
(43) Pub. Date: Aug. 30, 2012

(54) METHOD FOR FABRICATING SEMICONDUCTOR DEVICE

(76) Inventor: Chai-O CHUNG, Gyeonggi-do (KR)

(21) Appl. No.: 13/337,405

(22) Filed: Dec. 27, 2011

(30) Foreign Application Priority Data
Feb. 28, 2011 (KR) 10-2011-0017720

(51) Int. Cl. H01L 21/311

(52) U.S. Cl. 438/696; 257/E21.249

(57) ABSTRACT

A method for fabricating a semiconductor device includes forming a trench over a substrate, forming a spin on dielectric (SOD) layer in a first part of the trench, and forming an oxide layer within the trench, where the oxide layer is formed over the SOD layer by using a process for plasma chemical vapor deposition.

### CROSS-REFERENCE TO RELATED APPLICATIONS

The present application claims priority of Korean Patent Application No. 10-2011-0017720, filed on Feb. 28, 2011, which is incorporated herein by reference in its entirety.

### BACKGROUND

1. Field

Exemplary embodiments of the present invention relate to a method for fabricating a semiconductor device, and more particularly, to a method for gap-filling a narrow trench with an insulation layer. Exemplary embodiments of the present invention may be applied to a case in which an insulation layer is buried between gate lines adjacent to each other or a case in which an insulation layer is buried in a narrow hole or a narrow trench.

2. Description of the Related Art

As the miniaturization of semiconductor devices rapidly progresses, it becomes difficult to bury an insulation layer in an engraved pattern such as a narrow hole or trench. As the aspect ratio of a narrow pattern is increased, a void may occur in a buried insulation layer or a crack may occur in a buried insulation layer while a high-temperature process is performed. Such a void or crack degrades the characteristic of a semiconductor device.

In particular, when manufacturing a memory device having a critical dimension (CD) of 40 nm or less, an issue may arise while a trench between gate lines is gap-filled with an insulation layer, due to a CD reduction of the gate lines. When an insulation material subject to a subsequent heat treatment process at 800° C. or more is used as a gap-fill material, it becomes difficult to secure an operation current for driving a memory cell, due to the movement of dopant between device channels. Accordingly, an electrical characteristic may be degraded.

FIG. 1 is a cross-sectional view of a conventional semiconductor device. Referring to FIG. 1, a plurality of gates (or gate lines) 15 are arranged over a semiconductor substrate 10. Each of the gates 15 includes a gate electrode material (11 and 12) and a gate hard mask 13 over the substrate 10. The gate electrode material may have a stacked structure of a lower gate electrode material 11 and an upper gate electrode material 12. A liner layer 17 is formed over the semiconductor substrate 10 including the gates 15, and an insulation layer 19 is buried between the gates 15.

At this time, a borophosphosilicate glass (BPSG) layer using a flow characteristic through a subsequent heat treatment is used as the buried insulation layer 19. The BPSG layer has an excellent flow characteristic at a high temperature of 800° C. or more. However, the BPSG layer has a disadvantage in that a nitride layer for protecting the gates is significantly damaged during a wet thermal treatment. Furthermore, an etch rate for a cleaning chemical increases during a low-temperature heat treatment, compared with a high-temperature heat treatment. Therefore, it is not easy to secure an insulation isolation layer between the gates.

Due to the temperature limits of the subsequent heat treatment for the BPSG layer, an insulation layer which may be buried and densified through a subsequent heat treatment at 700° C. or less is useful.

FIG. 2 is a cross-sectional view of another conventional semiconductor device. Referring to FIG. 2, a plurality of gates (or gate lines) 25 are arranged over a semiconductor substrate 20. Each of the gates 25 includes a gate electrode material 21 and 22 and a gate hard mask 23 which are sequentially stacked. The gate electrode material may have a stacked structure of a lower gate electrode material 21 and an upper gate electrode material 22. A liner layer 27 is formed over the semiconductor substrate 20 including the gates 25, and a spin on dielectric (SOD) layer serving as a buried insulation layer 29 is buried between the gates 25.

The SOD layer 29 is formed to such a thickness of 5,000 to 5,500 Å as to completely fill the trenches between the gates 25, cured at a temperature of 700° C., and then planarized.

The SOD layer 29 not only exhibits an excellent flow characteristic but also may be densified (for example, formed to have less void by curing) at a relatively low temperature of 700° C. or less. However, when the SOD layer 29 is densified at 700° C., a crack 30 may occur due to a stress and an excessive shrinkage rate.

Such a crack 30 may degrade the electrical characteristic of a device.

### SUMMARY

An embodiment of the present invention is directed to a semiconductor device fabrication method for forming a buried insulation layer which exhibits an excellent gap-fill characteristic, has no crack, and shows a stable thin-film characteristic during a subsequent high-temperature heat treatment.

In accordance with an embodiment of the present invention, a method for fabricating a semiconductor device includes: forming a trench over a substrate; forming a spin on dielectric (SOD) layer in a first part of the trench; and forming an oxide layer within the trench, wherein the oxide layer is formed over the SOD layer by using a process for plasma chemical vapor deposition.

The forming of the SOD layer may include: applying the SOD layer onto the substrate including the trench; densifying the applied SOD layer; and etching the densified SOD layer such that the SOD layer remains in the first part of the trench.

### BRIEF DESCRIPTION OF THE DRAWINGS

FIG. 1 is a cross-sectional view of a conventional semiconductor device.

FIG. 2 is a cross-sectional view of another conventional semiconductor device.

FIGS. 3 to 8 are cross-sectional views illustrating a method for fabricating a semiconductor device in accordance with an embodiment of the present invention.

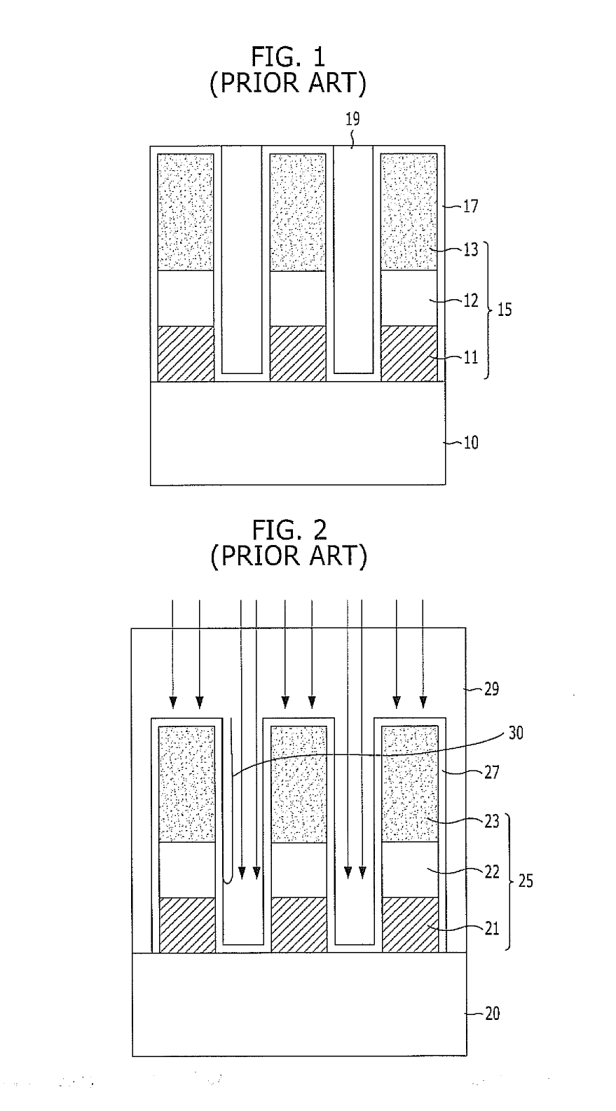

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

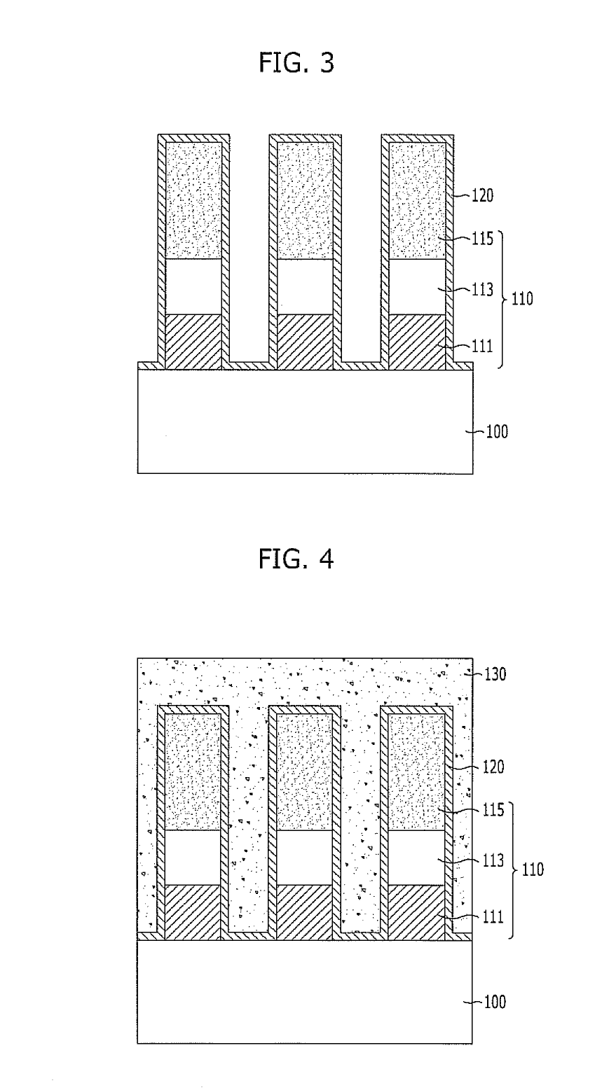

FIGS. 3 to 8 are cross-sectional views illustrating a method for fabricating a semiconductor device in accordance with an embodiment of the present invention.

Referring to FIG. 3, a gate electrode material and a gate hard mask material are sequentially deposited over a semiconductor substrate 100. The gate hard mask material and the gate electrode material are sequentially patterned through a photo and etching process or the like, thereby forming a plurality of gates (or gate lines) 110. Each of the gates 110 includes a gate electrode layer and a gate hard mask layer 115. The hard mask layer 115 may include nitride. The gate electrode layer may have a stacked structure of a polysilicon layer 111 and a metal layer 113. The metal layer 113 may include tungsten.

Although not illustrated in the drawing, a gate dielectric layer may be further formed between the gate 110 and the semiconductor substrate 100. Furthermore, a gate spacer for protecting a gate electrode may be further formed on the sidewalls of the gate 110. The gate spacer may include nitride.

A liner layer 120 is formed over the semiconductor substrate 100 including the gates 110. The liner layer 120 may include oxide. The liner layer 120 may include low pressure tetra ethyl ortho silicate (LPTEOS) which has an excellent step coverage and excellent film quality and is formed in a furnace. The liner layer 120 may include silicon oxide (SiO₂) formed through O₃-TEOS reaction of a thermal chemical vapor deposition (CVD) method. At this time, the liner layer 120 may be deposited to a thickness corresponding to 40˜60% of a distance between the gates.

Referring to FIG. 4, a cleaning process using 300:1 buffered oxide etch (BOE) is performed to control coating defects which may occur during a subsequent coating process for an SOD layer. After the cleaning process, the liner layer 120 is coated with an SOD layer 130 to primarily fill the trenches between the gates 110. The SOD layer 130 may be deposited by a spin coating method. The SOD layer 130 may be formed to a thickness of 3,000 to 5,000 Å so as to be deposited to a minimum/small thickness over the gates 110.

A soft baking process may be performed to remove impurities such as organic solvents. The soft baking process may be performed at 150° C. for about three minutes. After the soft baking process, a densification (curing) process of the SOD layer 130 is performed. The densification process may include performing a wet thermal treatment in a catalytic water vapor generator (cWVG) type furnace.

At this time, the densification process may be performed at a maximum heat treatment temperature which is set in the range of 300 to 400° C. The densification process may include curing a wafer at an intermediate temperature through multiple steps, without performing the densification process at the maximum temperature immediately after the wafer is loaded in a furnace.

Furthermore, the densification process may be performed in a state in which the percentage of the wet process is set to 40 to 80%. The densification process may include curing the SOD layer at multiple steps while the percentage of the wet process is successively changed at the same temperature.

The densification process may be performed while the pressure of the furnace is maintained at the level of an atmospheric pressure of 400˜700 Torr. The densification process may be performed for 40˜60 minutes. The densification process may be performed in such a manner that the SOD layer 130 has a compressive stress.

After the densification process, a hot de-ionizer water (DI) process may be performed in such a manner that the film quality of the SOD layer 130 is improved and the SOD layer 130 has an additional compressive stress. The hot DI process may include spraying wafer (H₂O) having a temperature of 100 to 150° C. for 10 to 20 minutes. After the hot DI process, the compressive stress of the SOD layer 130 may be further increased by 20 to 50% than the compressive stress of the SOD layer 130 during the densification process.

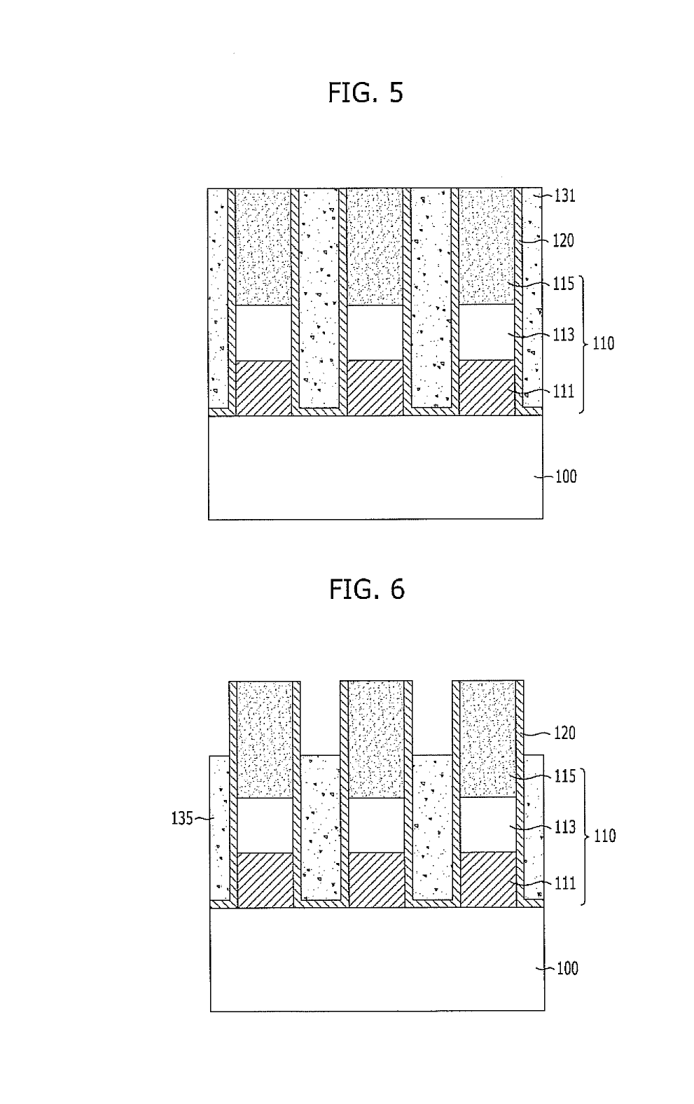

Referring to FIGS. 5 and 6, the SOD layer (130 in FIG. 4) is primarily polished by a chemical mechanical polishing (CMP) process to isolate the gates 110 and form polished SOD layer 131. The polished SOD layer 131 is buried between the gates 110 and isolated from each other. During the primary CMP process, the liner layer 120 over the gates 110 may be partially removed.

A wet etching process is performed to remove a part of the SOD layer 131 buried between the gates 110. The wet etching process is performed using a 300:1 BOE chemical to remove a part of the SOD layer 131. At this time, the SOD layer 131 may be removed by 800˜1,200 Å. After the wet etching, the SOD layer 135 remains between the gates 110.

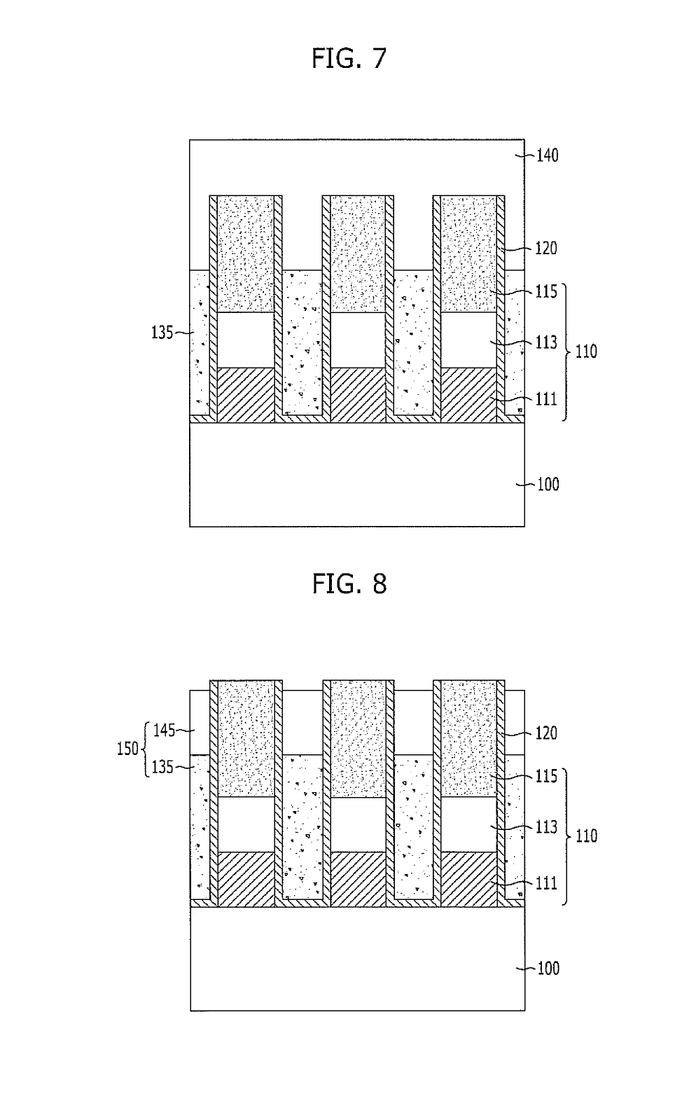

Referring to FIG. 7, a high-density plasma oxide layer 140 is secondarily buried between the gates 110 where a part of the SOD layer 130 was removed. When the high-density plasma oxide layer 140 is formed, the SOD layer 135 which is the primarily-buried material under the high-density plasma oxide layer 140 may be further densified. The high-density plasma oxide layer 140 may be deposited at a deposition temperature of 320 to 340° C. At this time, cold He gas may be injected onto the rear surface of the wafer such that a low temperature is maintained during the deposition process of the high-density plasma oxide layer 140. Accordingly, a plasma damage which may occur during the high-density plasma process may be controlled/reduced.

The deposition of the high-density plasma oxide layer 140 and an etching process may be repetitively performed to fill the trenches between the gates 110. During the deposition of the high-density plasma oxide layer 140, a flow rate of SiH₄ gas may be set to 20˜30 sccm, and a flow rate of O₂ gas may be set to 45-55 sccm. At this time, in order to suppress a loss of the nitride serving as the gate hard mask layer 115, a relatively low bias power ranging from 1,400 to 1,800 W may be applied. In order to bury the high-density plasma oxide layer 140, an in-situ etching process using NF₃ gas may be performed. At this time, a flow rate of NF₃ gas may be set to 100˜150 sccm. The deposition and etching process may be performed ten or more times.

Referring to FIG. 8, a secondary CMP process for isolating the gates 110 is performed to etch the high-density plasma oxide layer 140. Therefore, the high-density plasma oxide layer 145 remains over the SOD layer 135 between the gates 110. Accordingly, a buried insulation layer 150 including the SOD layer 135 and the high-density plasma oxide layer 140 is formed between the gates 110.

In the above-described embodiment of the present invention, the densification process for the SOD layer 130 is performed at a relatively low temperature of 300° C. to suppress a rapid shrinkage of the SOD layer. The stress of the SOD layer, which was thermally treated through the post-processing process using the hot DI process after the densification process of the SOD layer, may be changed into a compressive stress. Furthermore, as the stacked structure of the densified SOD layer and the high-density plasma oxide layer having a compressive stress is buried between the gates, a crack of the buried insulation layer caused by a stress variation during the subsequent high-temperature heat treatment at 700° C. may be prevented.

In the embodiment of the present invention, it has been described that the insulation layer is buried between the narrow trench between gate patterns adjacent to each other. The present invention may be applied to a case in which an insulation layer is buried in a narrow trench having a large aspect ratio as well as the case in which the insulation layer is buried between the gates.

In accordance with the embodiment of the present invention, the SOD layer which is densified at a low temperature of 300 to 400° C. at which no stress variations and excessive shrinkage occurs is buried in a part of the narrow trench, and the high density plasma chemical vapor deposition (HDPCVD) oxide layer which exhibits an excellent burial characteristic and film quality at a temperature of 320 to 340° C. and has a compressive stress is buried in the rest of the narrow trench. Therefore, although a high-temperature heat treatment at 700° C. is subsequently performed, the deformation of the buried insulation layer caused by a stress variation may be substantially prevented. Accordingly, an insulation layer without cracks and micro pores may be formed in a narrow trench.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a trench over a substrate;
forming a spin on dielectric (SOD) layer in a part of the trench; and
forming an oxide layer within the trench, wherein the oxide layer is formed over the SOD layer by using a process for a high density plasma process.

2. The method of claim 1, wherein the high density plasma process includes a high density plasma chemical vapor deposition.

3. The method of claim 1, wherein the forming of the SOD layer comprises:
applying the SOD layer on the substrate including the trench;
densifying the applied SOD layer; and
etching the densified SOD layer such that the SOD layer remains in the part of the trench.

4. The method of claim 3, wherein the densifying of the SOD layer is performed through a heat treatment at a temperature of 300 to 400° C.

5. The method of claim 4, wherein the heat treatment is performed at multiple steps while the temperature is raised at each subsequent stage.

6. The method of claim 5, wherein the heat treatment is performed at a pressure of 400 to 700 Torr for 40 to 60 minutes.

7. The method of claim 3, further comprising post-processing the SOD layer using a de-ionizer water (DI) solution after the densifying of the SOD layer.

8. The method of claim 7, wherein the post-processing of the SOD layer is performed by spraying H₂O at a temperature of 100 to 150° C. for 10 to 20 minutes.

9. The method of claim 1, wherein the high density plasma process is performed at a temperature of 320 to 340° C.

10. A method for fabricating a semiconductor device, comprising:
forming gates over a substrate, wherein the gates are separated from each other by a trench;
forming an SOD layer in a lower portion of the trench; and
forming an oxide layer in the trench, wherein the oxide layer is formed over the SOD layer by using a process for a high density plasma process.

11. The method of claim 10, wherein the high density plasma process includes a high density plasma chemical vapor deposition.

12. The method of claim of claim 10, wherein the forming of the SOD layer comprises:
applying the SOD layer on the substrate including the trench;
densifying the applied SOD layer;
removing the SOD layer over the gates by polishing the SOD layer through a chemical mechanical polishing (CMP) process; and
etching the SOD layer such that the SOD layer remains in the lower portion of the trench.

13. The method of claim 12, wherein the densifying of the SOD layer is performed through a heat treatment at a temperature of 300 to 400° C.

14. The method of claim 13, wherein the heat treatment is performed at multiple steps while the temperature is raised at each subsequent stage.

15. The method of claim 14, wherein the heat treatment is performed at a pressure of 400 to 700 Torr for 40 to 60 minutes.

16. The method of claim 12, further comprising post-processing the SOD layer using a de-ionizer water (DI) solution after the densifying of the SOD layer.

17. The method of claim 16, wherein the post-processing of the SOD layer is performed by spraying H₂O at a temperature of 100 to 150° C. for 10 to 20 minutes.

18. The method of claim 10, wherein the a high density plasma process is performed at a temperature of 320 to 340° C.
